(19) United States
(12) Patent Application Publication
(10) Pub. No.: US 2023/0275137 A1
(43) Pub. Date: Aug. 31, 2023

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Tsuyoshi KACHI, Kanazawa Ishikawa (JP)

(21) Appl. No.: 17/880,478

(22) Filed: Aug. 3, 2022

(30) Foreign Application Priority Data
Feb. 28, 2022 (JP) 2022-029794

(51) Int. Cl. H01L 29/423; H01L 29/10; H01L 29/40; H01L 29/06; H01L 29/78

(52) U.S. Cl. CPC H01L 29/4236; H01L 29/1095; H01L 29/407; H01L 29/0696; H01L 29/7813

(57) ABSTRACT

A semiconductor device includes first, second and control electrodes, a semiconductor part and a conductive body. The semiconductor part is provided between the first and second electrodes. The semiconductor part includes a first layer of a first conductivity type, and a second layer of a second conductivity type. The second layer is provided between the first layer and the first electrode. The conductive body is provided in the semiconductor part, and faces the first layer via a first insulating film. The control electrode is provided between the second layer and the first electrode. The control electrode is apart from the conductive body. The control electrode includes first and second parts linked to each other. The first part faces the second layer via a second insulating film in a first direction. The second part faces the second layer along a second direction orthogonal to the first direction.

### CROSS-REFERENCE TO RELATED APPLICATIONS

This application is based upon and claims the benefit of priority from Japanese Patent Application No. 2022-029794, filed on Feb. 28, 2022; the entire contents of which are incorporated herein by reference.

### FIELD

Embodiments relate to a semiconductor device.

### BACKGROUND

It is desirable for a semiconductor device used in power control to reduce the on-resistance and improve switching characteristics.

### BRIEF DESCRIPTION OF THE DRAWINGS

FIG. 1 is a schematic cross-sectional view showing a semiconductor device according to an embodiment;

FIGS. 2A and 2B are partial cross-sectional views schematically showing the semiconductor device according to the embodiment;

FIG. 3 is a graph showing characteristics of the semiconductor device according to the embodiment;

FIGS. 4A to 8B are schematic cross-sectional views showing manufacturing processes of the semiconductor device according to the embodiment; and

FIGS. 9A and 9B are schematic cross-sectional views showing semiconductor devices according to modifications of the embodiment.

### DETAILED DESCRIPTION

According to one embodiment, a semiconductor device includes a first electrode, a second electrode, a semiconductor part, a conductive body and a control electrode. The second electrode is apart from the first electrode in a first direction. The semiconductor part is provided between the first electrode and the second electrode. The semiconductor part includes a first semiconductor layer of a first conductivity type, and a second semiconductor layer provided between the first semiconductor layer and the first electrode, the second semiconductor layer being of a second conductivity type. The conductive body is provided in the semiconductor part and electrically insulated from the semiconductor part by a first insulating film. The conductive body faces the first semiconductor layer via the first insulating film. The control electrode is provided between the second semiconductor layer and the first electrode. The control electrode is apart from the conductive body. The control electrode includes a first part and a second part linked to the first part. The first part faces the second semiconductor layer via a second insulating film. The second part faces the second semiconductor layer via the second insulating film along a second direction. The second direction is orthogonal to the first direction.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

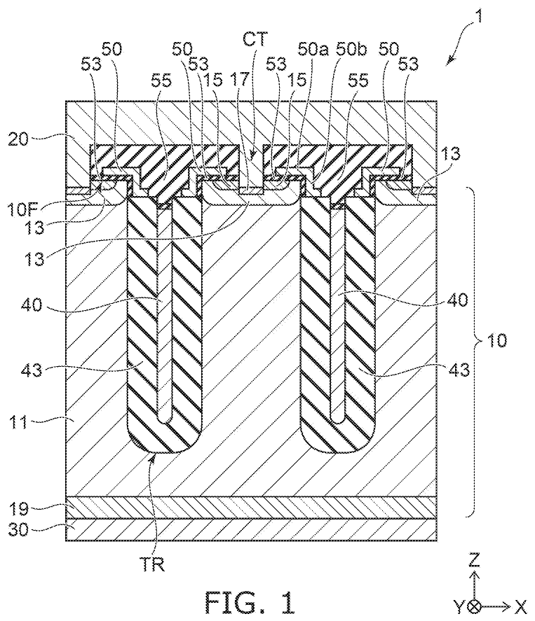

FIG. 1 is a schematic cross-sectional view showing a semiconductor device 1 according to an embodiment. The semiconductor device 1 is, for example, a power MOSFET. The semiconductor device 1 includes, for example, a semiconductor part 10, a first electrode 20, and a second electrode 30.

The semiconductor part 10 is, for example, silicon. The semiconductor part 10 is provided between the first electrode 20 and the second electrode 30. The first electrode 20 is, for example, a source electrode. The second electrode 30 is, for example, a drain electrode.

The semiconductor part 10 includes a first semiconductor layer 11 of a first conductivity type, a second semiconductor layer 13 of a second conductivity type, a third semiconductor layer 15 of the first conductivity type, a fourth semiconductor layer 17 of the second conductivity type, and a fifth semiconductor layer 19 of the first conductivity type. In the following description, for example, the first conductivity type is an n-type; the second conductivity type is a p-type; but the first and second conductivity types are not limited thereto.

The first semiconductor layer 11 is, for example, an n-type drift layer. The first semiconductor layer 11 extends between the first electrode 20 and the second electrode 30.

The second semiconductor layer 13 is, for example, a p-type base layer. The second semiconductor layer 13 is provided on the first semiconductor layer 11. The second semiconductor layer 13 includes a surface that is included in an upper surface 10F of the semiconductor part 10.

The third semiconductor layer 15 is, for example, an n-type source layer. The third semiconductor layer 15 is partially provided on the second semiconductor layer 13. The third semiconductor layer 15, for example, has a first-conductivity-type impurity concentration higher than a first-conductivity-type impurity concentration of the first semiconductor layer 11. The third semiconductor layer 15 is electrically connected to the first electrode 20.

The fourth semiconductor layer 17 is, for example, a p-type contact layer. The fourth semiconductor layer 17 is partially provided on the second semiconductor layer 13. The fourth semiconductor layer 17 has a second-conductivity-type impurity concentration higher than a second-conductivity-type impurity concentration of the second semiconductor layer 13.

The first electrode 20 is in contact with the fourth semiconductor layer 17 and electrically connected thereto. The first electrode is electrically connected to the second semiconductor layer 13 via the fourth semiconductor layer 17.

The fifth semiconductor layer 19 is provided between the first semiconductor layer 11 and the second electrode 30. The fifth semiconductor layer 19 is, for example, an n-type buffer layer. The fifth semiconductor layer 19 is electrically connected to the second electrode 30. The fifth semiconductor layer 19 has a first-conductivity-type impurity concentration higher than the first-conductivity-type impurity concentration of the first semiconductor layer 11.

The semiconductor device 1 further includes a conductive body 40 and a control electrode 50. The semiconductor part 10 includes a trench TR having a depth capable of extending into the first semiconductor layer 11 from the surface of the second semiconductor layer 13.

The conductive body 40 is, for example, a field plate electrode and is provided inside the trench TR. The conductive body 40 is electrically insulated from the semiconductor part 10 by a first insulating film 43. The conductive body 40 faces the first semiconductor layer 11 via the first insulating film 43. The first insulating film 43 is, for example, a field plate insulating film covering the inner surface of the trench TR.

The control electrode 50 includes, for example, a first part 50a and a second part 50b. The first part 50a is provided on the front surface 10F of the semiconductor part 10. The second part 50b is provided inside the trench TR. The second part 50b is apart from the conductive body 40 inside the trench TR. The second part 50b is provided on the inner wall of the trench TR and is linked to the first part 50a. The first part 50a and the second part 50b are formed as a continuous body. The distance in the Z-direction from the second electrode 30 to the conductive body 40 is less than the distance in the Z-direction from the second electrode 30 to the control electrode 50.

The second part 50b of the control electrode 50 is provided on, for example, the first insulating film 43. The control electrode 50 includes an end portion that extends in a direction crossing the inner wall of the trench TR, e.g., an X-direction. The end portion of the control electrode 50 extends along the upper end of the first insulating film 43. Such a cross-sectional shape of the control electrode 50 is an example; and the cross-sectional shape may not include the end portion extending in the X-direction.

The control electrode 50 is electrically insulated from the semiconductor part 10 by a second insulating film 53. The second insulating film 53 is, for example, a gate insulating film. The first and second parts 50a and 50b of the control electrode 50 face the second semiconductor layer 13 via the second insulating film 53.

The second semiconductor layer 13 ha a top surface positioned in the upper surface of the semiconductor part 10. The top surface of the second semiconductor layer 13 faces the first part 50a of the control electrode 50. The second semiconductor layer 13 has a side surface included in the inner wall of the trench TR. The side surface of the second semiconductor layer 13 faces the second part 5013 of the control electrode 50. The third semiconductor layer 15 includes a portion that faces the first part 50a of the control electrode 50 via the second insulating film 53 at the upper surface 10F of the semiconductor part 10.

The first electrode 20 covers the third semiconductor layer 15, the fourth semiconductor layer 17, the conductive body 40, and the control electrode 50 at the front surface 10F side of the semiconductor part 10. A third insulating film 55 is provided between the first electrode 20 and the conductive body 40 and between the first electrode 20 and the control electrode 50. The conductive body 40 and the control electrode 50 are electrically insulated from the first electrode 20 by the third insulating film 55. The third insulating film 55 is, for example, an inter-layer insulating film.

The first electrode 20 is electrically connected to the third and fourth semiconductor layers 15 and 17 via a contact trench CT provided in the third insulating film 55 and the semiconductor part 10. The contact trench CT has, for example, a depth capable of extending into the second semiconductor layer 13 from the upper surface of the third insulating film 55. The fourth semiconductor layer 17 is provided at the bottom surface of the contact trench CT. The first electrode 20 is in contact with the third semiconductor layer 15 and electrically connected thereto. The third semiconductor layer 15 is included in the inner wall of the contact trench CT.

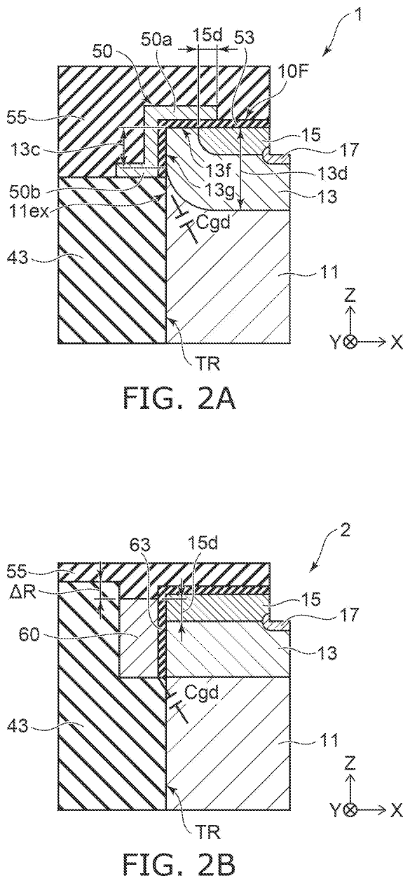

FIG. 2A is a partial cross-sectional view schematically showing the semiconductor device 1 according to the embodiment. FIG. 2B is a partial cross-sectional view schematically showing a semiconductor device 2 according to a comparative example. FIGS. 2A and 2B each illustrate a part around the opening of the trench TR.

As shown in FIG. 2A, the second semiconductor layer 13 includes a first surface 13f (the top surface) included in the upper surface 10F of the semiconductor part 10, and a second surface 13g included in the inner wall of the trench TR. The first surface 13f of the second semiconductor layer 13 faces the first part 50a of the control electrode 50 via the second insulating film 53. The second surface 13g faces the second part 50b of the control electrode 50 via the second insulating film 53. The gate length of the control electrode 50 is the creepage distance from the third semiconductor layer 15 to the first semiconductor layer 11 via the first and second surfaces 13f and 13g.

“13c” in FIG. 2A is a first distance in the Z-direction from the first surface 13f to the boundary between the first semiconductor layer 11 and the second semiconductor layer 13. The first distance 13c is defined along the second surface 13g. “13d” in FIG. 2A is a second distance in the Z-direction from the upper surface 10F of the semiconductor part 10 to the boundary between the first semiconductor layer 11 and the second semiconductor layer 13 at a position apart from the trench TR. In other words, the second distance 13d is defined in the Z-direction between the boundary of the second insulating film 53 and the third semiconductor layer 15 and the boundary of the first semiconductor layer 11 and the second semiconductor layer 13. In the semiconductor device 1, the first distance 13c is less than the second distance 13d. That is, the first semiconductor layer 11 includes an extension portion 11ex extending along the inner wall of the trench TR. The extension portion 11ex is provided between the second semiconductor layer 13 and the second part 50b of the control electrode 50.

The extension portion 11ex, for example, is depleted by a built-in potential between the first semiconductor layer 11 and the second semiconductor layer 13. Thereby, it is possible to reduce a parasitic capacitance Cgd between the gate and drain.

The third semiconductor layer 15 includes an overlapping region that faces the first part 50a of the control electrode 50 via the second insulating film 53. The third semiconductor layer 15 provides an overlapping width 15d by facing the control electrode 50. The overlapping width 15d is, for example, the diffusion distance of the first-conductivity-type impurity inside the third semiconductor layer 15. The overlapping width 15d is controlled by the process conditions such as heat treatment temperature after ion implantation and a dose amount of the first-conductivity-type impurity under which the third semiconductor layer 15 is formed.

As shown in FIG. 2B, the semiconductor device 2 includes a control electrode 60 provided inside the trench TR. The control electrode 60 faces the second and third semiconductor layers 13 and 15 via a second insulating film 63 at the inner wall of the trench TR.

In the example, the uniform distance is provided between the upper surface 10F of the semiconductor part 10 and the boundary of the first semiconductor layer 11 and the second semiconductor layer 13. In other words, the first semiconductor layer 11 does not include the extension portion 11ex that extends between the second semiconductor layer 13 and the control electrode 60. Therefore, in the semiconductor device 2, a parasitic capacitance Cgd between gate and drain is greater than the parasitic capacitance Cgd of the semiconductor device 1.

The third semiconductor layer 15 includes an overlapping region that overlaps the control electrode 60 via the second insulating film 63 at the inner wall of the trench TR. The overlapping width 15d in the Z-direction is dependent on, for example, a recess amount ΔR of the control electrode 60 with respect to the upper surface 10F of the semiconductor part 10. The control electrode 60 is formed to have a prescribed length in Z-direction by, for example, dry etching. Thus, the recess amount ΔR includes nonuniformities of etching. When the recess amount ΔR is large and the overlapping region of the third semiconductor layer 15 disappears, for example, the semiconductor device 2 will no longer turn on. Although it is preferable to reduce the recess amount ΔR and increase the overlapping width 15d to avoid such a defect, a parasitic capacitance Cgs between gate and source increases. In contrast, in the semiconductor device 1, the overlapping width 15d is easily controlled and can be reduced. That is, the parasitic capacitance Cgs between gate and source can be reduced.

Thus, in the semiconductor device 1, the parasitic capacitance Cgs between gate and source and the parasitic capacitance Cgd between gate and drain can be reduced. Thereby, it is possible to improve the switching characteristics.

In the semiconductor device 1, the manufacturing processes are easier because the control electrode 50 can be formed to be thin. It is possible in the control electrode 50 to eliminate structural defects such as voids and the like that is generated in the control electrode 60 while filling the trench TR.

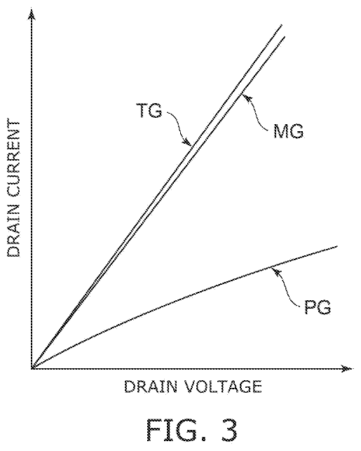

FIG. 3 is a graph showing characteristics of the semiconductor device 1 according to the embodiment. The horizontal axis is the drain voltage. The vertical axis is the drain current. “MG” in the figure is the characteristic of the semiconductor device 1. “TG” is the characteristic of a trench gate transistor; and “PG” is the characteristic of a planar gate transistor. The channel lengths of the transistors are equal.

As shown in FIG. 3, the drain current of the planar gate transistor is not more than one half of the drain current of the trench gate transistor. In other words, the on-resistance of the planar transistor is greater than the on-resistance of the trench gate transistor.

In contrast, the drain current of the semiconductor device 1 is substantially equal to the drain current of the trench gate transistor.

In the semiconductor device 1, the control electrode 50 includes the planar gate part (the first part 50a) and the trench gate part (the second part 50b), and the planar gate part faces the third semiconductor layer 15 via the second insulating film 53. Thereby, it is possible to improve the controllability of the overlapping width 15d. In other words, it is possible to improve the controllability of the overlapping region width of the gate electrode that faces the source layer via the gate insulating film, and reduce the parasitic capacitance. Moreover, whereas the control electrode 50 includes the planar gate part, the on-resistance of the semiconductor device 1 can be substantially equal to the on-resistance of the trench gate transistor.

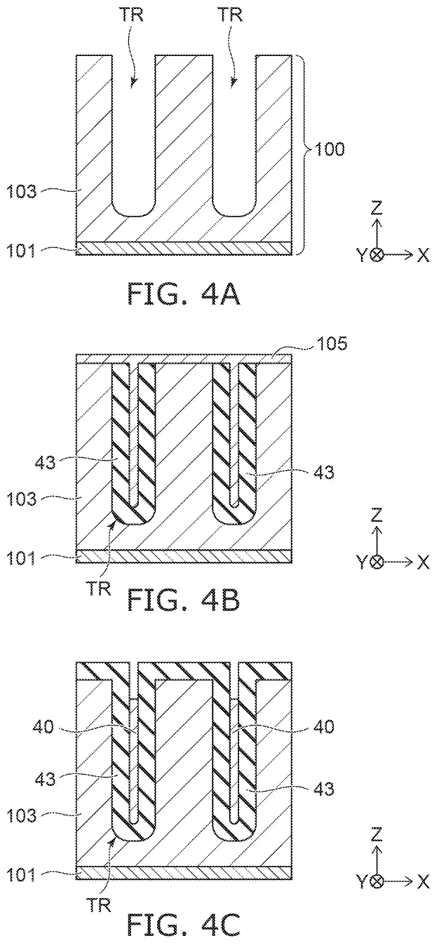

A method for manufacturing the semiconductor device 1 is described below with reference to FIGS. 4A to 8B. FIGS. 4A to 8B are schematic cross-sectional views showing manufacturing processes of the semiconductor device 1 according to the embodiment.

The semiconductor device 1 is manufactured using, for example, a silicon wafer 100. The silicon wafer 100 includes an n-type silicon substrate 101 and an n-type silicon layer 103. The n-type silicon layer 103 is epitaxially grown on the n-type silicon substrate 101. The n-type silicon layer 103 has an n-type impurity concentration less than an n-type impurity concentration of the n-type silicon substrate 101.

As shown in FIG. 4A, the trench TR is formed in the upper surface side of the n-type silicon layer 103. The trench TR is formed by selectively etching the n-type silicon layer 103. The n-type silicon layer 103 is partially removed using, for example, RIE (Reactive Ion Etching).

As shown in FIG. 4B, the first insulating film 43 is formed to cover the inner surface of the trench TR. The first insulating film 43 is, for example, a silicon oxide film. The first insulating film 43 includes, for example, a silicon oxide film formed by thermal oxidation of the n-type silicon layer 103 and another silicon oxide film deposited by CVD (Chemical Vapor Deposition). The first insulating film 43 is formed so that a space remains inside the trench TR.

Continuing, a conductive layer 105 is formed on the first insulating film 43 so that the internal space of the trench TR is filled with the conductive layer 105. The conductive layer 105 is, for example, conductive polysilicon. The conductive layer 105 is formed by, for example, CVD.

As shown in FIG. 4C, the conductive body 40 is formed inside the trench TR. The conductive body 40 is formed by partially removing the conductive layer 105. The conductive layer 105 is removed by, for example, dry etching or wet etching.

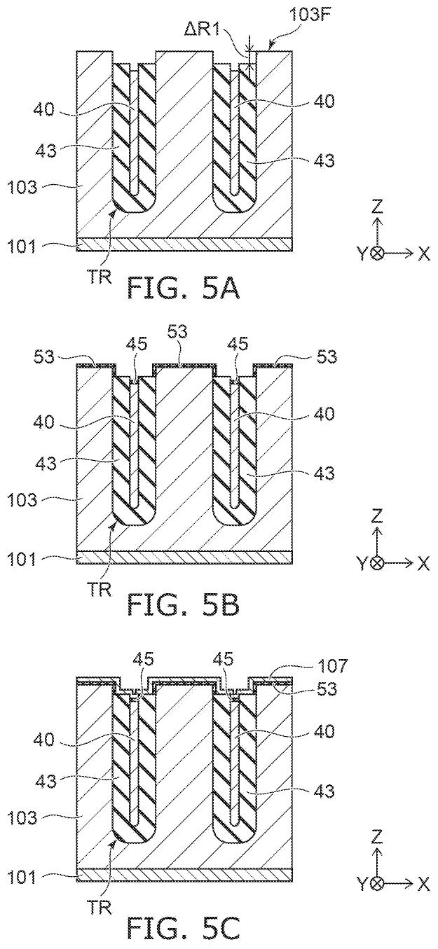

As shown in FIG. 5A, the first insulating film 43 is partially etched to expose the inner wall of the trench TR at the upper portion thereof. The first insulating film 43 is partially removed by, for example, dry etching. The etching amount of the first insulating film 43 is controlled so that a recess amount ΔR1 is a prescribed value with respect to an upper surface 103F of the n-type silicon layer 103.

As shown in FIG. 5B, the second insulating film 53 is formed on the n-type silicon layer 103. The second insulating film 53 covers the inner wall at the upper portion of the trench TR. The second insulating film 53 is formed by, for example, thermal oxidation. At this time, an insulating film 45 also is formed on the upper end of the conductive body 40. The second insulating film 53 and the insulating film 45 are, for example, silicon oxide films.

As shown in FIG. 5C, a conductive layer 107 is formed to cover the first insulating film 43 and the second insulating film 53. The conductive layer 107 is, for example, conductive polysilicon. The conductive layer 107 is formed using, for example, CVD.

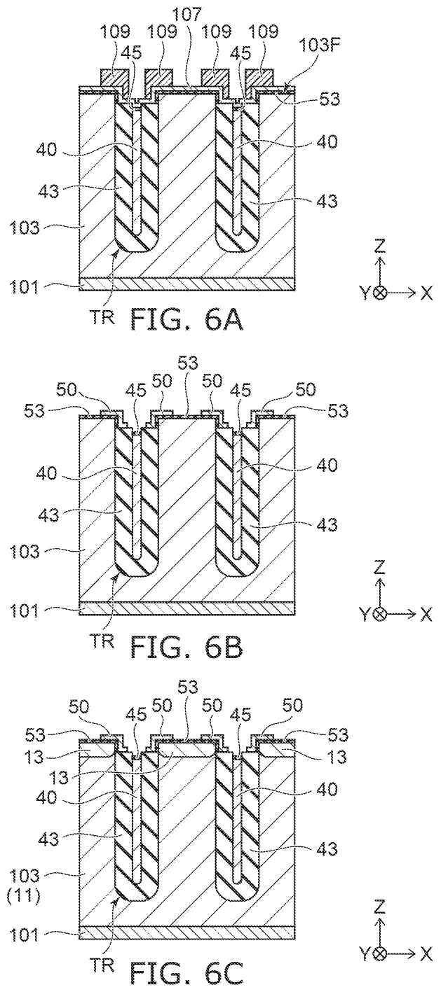

As shown in FIG. 6A, an etching mask 109 is formed on the conductive layer 107. The etching mask 109 is, for example, a photoresist. The etching mask 109 is formed to cover a portion of the upper surface 103F of the n-type silicon layer 103 and the inner wall of the trench TR. The etching mask 109 is formed using, for example, photolithography.

As shown in FIG. 6B, the control electrode 50 is formed by selectively etching the conductive layer 107 using the etching mask 109. The conductive layer 107 is removed by, for example, dry etching.

As shown in FIG. 6C, the second semiconductor layer 13 is formed at the upper surface side of the n-type silicon layer 103. Then, the first semiconductor layer 11 is provided between the second semiconductor layer 13 and the n-type silicon substrate 101. That is, the n-type silicon layer 103 is the first semiconductor layer 11.

The second semiconductor layer 13 is formed by selectively ion-implanting a p-type impurity such as boron (B) into the upper surface side of the n-type silicon layer 103. The control electrode 50 serves as an ion implantation mask. The ion-implanted p-type impurity is activated and diffused by heat treatment.

The second semiconductor layer 13 includes a surface 13g contacting the second insulating film 53 at the inner wall of the trench TR; and the Z-direction width of the surface 13g is the first distance 13c (see FIG. 2A). The recess amount ΔR1 of the first insulating film 43 (see FIG. 5A) is controlled to be greater than the first distance 13c. In other words, the control electrode 50 has the bottom surface at the second part 50b (see FIG. 2A). The second semiconductor layer 13 has a lower end at the side contacting the second insulating film 53. The bottom surface of the control electrode 50 is positioned in the Z-direction at a level lower than a level of the lower end of the second semiconductor layer 13.

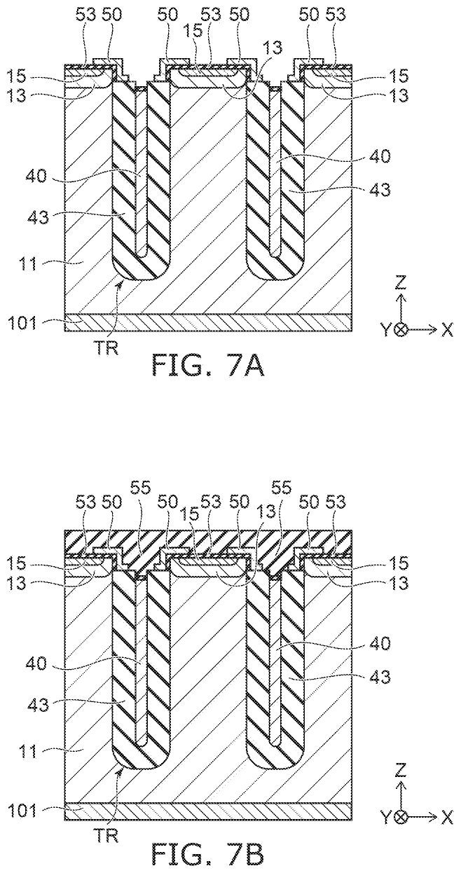

As shown in FIG. 7A, the third semiconductor layer 15 is formed on the second semiconductor layer 13. The third semiconductor layer 15 is formed by selectively ion-implanting an n-type impurity such as arsenic (As) into the upper surface side of the second semiconductor layer 13. The ion-implanted n-type impurity is activated by heat treatment. The control electrode 50 serves as an ion implantation mask.

The third semiconductor layer 15 includes an overlapping region that overlaps the first part 50a of the control electrode 50 in the Z-direction. The overlapping region of the third semiconductor layer 15 is provided with the overlapping width 15d (see FIG. 2A) that can be controlled by the heat treatment temperature after ion implantation or the dose of the ion-implanted n-type impurity. Therefore, the overlapping region of the third semiconductor layer 15 is formed uniformly in the whole wafer surface. Also, the overlapping width 15d is controlled easily.

As shown in FIG. 7B, the third insulating film 55 is formed to cover the control electrode 50 and the conductive body 40. The third insulating film 55 is, for example, a silicon oxide film. The third insulating film 55 is formed using, for example, CVD. The third insulating film 55 also covers the third semiconductor layer 15.

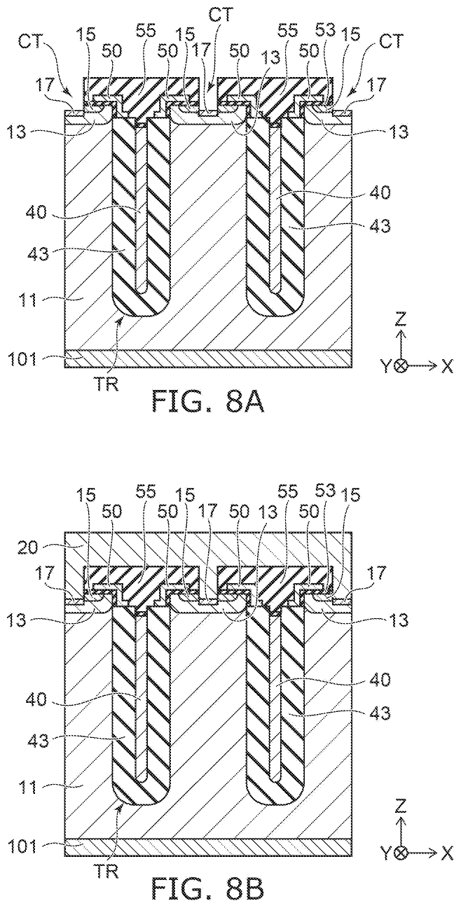

As shown in FIG. 8A, the contact trench CT is formed in the third insulating film 55. The contact trench CT is formed to a depth capable of extending into the second semiconductor layer 13 from the upper surface of the third insulating film 55. The fourth semiconductor layer 17 is formed at the bottom surface of the contact trench CT. The fourth semiconductor layer 17 is formed by ion-implanting a p-type impurity such as boron (B) into the second semiconductor layer 13 via the contact trench CT and by performing heat treatment for the activation.

As shown in FIG. 8B, the first electrode 20 is formed on the third insulating film 55. The first electrode 20 extends into the contact trench CT and contacts the third and fourth semiconductor layers 15 and 17. The first electrode 20 includes, for example, tungsten (W) and aluminum (Al).

Continuing, the backside of the n-type silicon substrate 101 is thinned by polishing or etching. The fifth semiconductor layer 19 (see FIG. 1) is formed thereby. Then, the second electrode 30 is formed on the back surface of the fifth semiconductor layer 19. The second electrode 30 includes, for example, nickel (Ni), aluminum (Al), silver (Ag), etc.

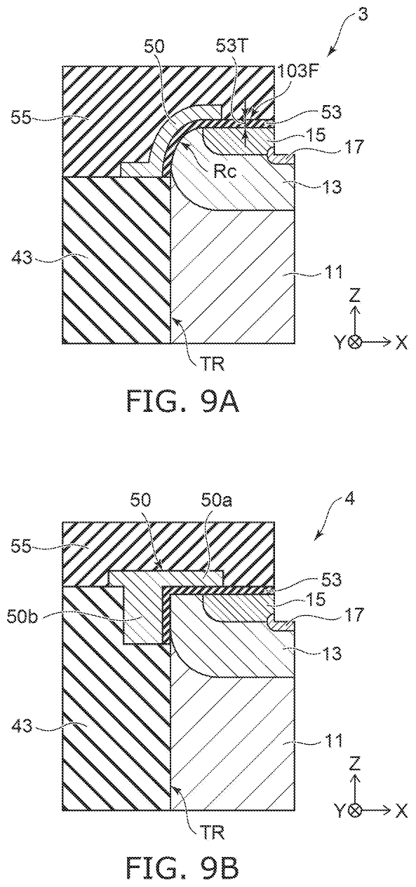

FIGS. 9A and 9B are schematic cross-sectional views showing semiconductor devices 3 and 4 according to modifications of the embodiment. FIGS. 9A and 9B each are partial cross-sectional views showing a portion around the opening of the trench TR.

In the semiconductor device 3 shown in FIG. 9A, the second semiconductor layer 13 includes a rounded corner at which the upper surface 10F of the semiconductor part 10 and the inner wall of the trench TR are linked. The corner of the second semiconductor layer 13 is formed to have, for example, a curvature radius Rc that is greater than a thickness 53T in the Z-direction of the second insulating film 53.

The corner of the second semiconductor layer 13 is rounded by, for example, dry etching while forming the trench TR. The corner of the second semiconductor layer 13 also is formed by thermal oxidation when forming the second insulating film 53. In other words, the inner surface of the trench TR is linked to the upper surface via the curved surface in the second semiconductor layer 13. The first and second parts 50a and 50b of the control electrode 50 (see FIG. 2A) cover the rounded corner of the second semiconductor layer 13. The first and second parts 50a and 50b are linked via a curved portion that has the curvature radius Rc. Thus, the second semiconductor layer 13 includes the rounded corner, and the second insulating film 53 has a uniform film thickness on the rounded corner. Thereby, it is possible to provide stable threshold voltage of the control electrode 50. Also, electric field concentration at the corner of the second semiconductor layer 13 can be suppressed, and the reliability of the second insulating film 53 can be increased.

In the semiconductor device 4 shown in FIG. 9B, the first and second parts 50a and 50b of the control electrode 50 are formed in different processes. The second part 50b is provided in a recess formed in the first insulating film 43. The recess of the first insulating film 43 is filled with the second part 50b. On the other hand, the first part 50a is formed by patterning a conductive layer formed on the first insulating film 43, the second part 50b, and the second insulating film 53. The first part 50a covers the top surface of the second semiconductor layer 13. Also, the first part 50a includes a portion extending from the upper end of the second part 50b toward the inside of the opening of the trench TR. In other words, for example, the first part 50a extends in the X-direction over the second semiconductor layer 13, the second part 50b and the first insulating film 43; and the upper end of the second part 50b is connected to the first part 50a.

In the example, the gate resistance of the control electrode 50 can be reduced by increasing the cross-sectional area of the second part 50b of the control electrode 50. Also, it is unnecessary to control the overlapping width 15d of the control electrode 50 and the third semiconductor layer 15 when forming the second part 50b (see FIG. 2B). Thus, the tolerance of the recess amount ΔR (see FIG. 2A) is increased, and the second part 50b is easily formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode apart from the first electrode in a first direction;
a semiconductor part provided between the first electrode and the second electrode, the semiconductor part including a first semiconductor layer of a first conductivity type, and a second semiconductor layer provided between the first semiconductor layer and the first electrode, the second semiconductor layer being of a second conductivity type;
a conductive body provided in the semiconductor part and electrically insulated from the semiconductor part by a first insulating film, the conductive body facing the first semiconductor layer via the first insulating film; and
a control electrode provided between the second semiconductor layer and the first electrode, the control electrode being apart from the conductive body,
the control electrode including a first part and a second part linked to the first part, a first part facing the second semiconductor layer via a second insulating film, the second part facing the second semiconductor layer via the second insulating film along a second direction, the second direction being orthogonal to the first direction.

2. The device according to claim 1, wherein
the semiconductor part further includes a third semiconductor layer partially provided on the second semiconductor layer, the third semiconductor layer is of the first conductivity type, and
the third semiconductor layer includes a portion facing the first part of the control electrode via the second insulating film.

3. The device according to claim 2, wherein
the third semiconductor layer has a first-conductivity-type impurity concentration higher than a first-conductivity-type impurity concentration of the first semiconductor layer.

4. The device according to claim 2, wherein
the first electrode is electrically connected to the second and third semiconductor layers, and
the control electrode and the conductive body are electrically insulated from the first electrode by a third insulating film.

5. The device according to claim 2, wherein
the second semiconductor layer has a first width in the first direction along the second insulating film, and
the first width is less than a second distance in the first direction from a boundary between the first semiconductor layer and the second semiconductor layer to a boundary between the second insulating film and the third semiconductor layer.

6. The device according to claim 2, wherein
a distance in the first direction from a boundary between the first semiconductor layer and the second semiconductor layer to the first part of the control electrode has a minimum at a surface of the second semiconductor layer facing the second part of the control electrode via the second insulating film.

7. The device according to claim 5, wherein
the first semiconductor layer includes an extension portion extending between the control electrode and the second semiconductor layer along the second insulating film.

8. The device according to claim 5, wherein
A first distance from the boundary between the first semiconductor layer and the second semiconductor layer to the first electrode through the third semiconductor layer is defined in the first direction, and
a second distance from an end at the second electrode side of the control electrode to the first electrode is defined in the first direction, the first distance being greater than the second distance.

9. The device according to claim 1, wherein
the conductive body is provided inside a trench having an opening at a surface of the semiconductor part at the first electrode side, and
the first insulating film covers an inner surface of the trench, and is provided between the conductive body and the first semiconductor layer.

10. The device according to claim 9, wherein
the first part of the control electrode is provided on the surface of the semiconductor part with the second insulating film interposed, and
the second part of the control electrode is provided inside the trench.

11. The device according to claim 10, wherein
a distance in the first direction from the conductive body to the second electrode is less than a distance in the first direction from the control electrode to the second electrode.

12. The device according to claim 1, wherein
the control electrode further includes a curved portion linking the first and second parts.

13. The device according to claim 12, wherein
a curvature radius of the curved portion of the control electrode is greater than a film thickness in the first direction of the second insulating film.

14. The device according to claim 1, wherein
the second part of the control electrode is provided in the first insulating film, and
the first part of the control electrode extends in the second direction over the first insulating film, the second part, and the second semiconductor layer, the first part being connected to an upper end of the second part.
